(19) United States
(12) Patent Application Publication
(10) Pub. No.: US 2025/0311091 A1
(43) Pub. Date: Oct. 2, 2025

(54) PCB WITH BREAKOUT TO ENABLE HIGHER DENSITY, LAYER COUNT AND ENHANCED PERFORMANCE

(71) Applicant: Cisco Technology, Inc., San Jose, CA (US)

(72) Inventors: Mingjian Gao, Shanghai (CN); Mingtong Zuo, Shanghai (CN); Wenbin Ma, Shanghai (CN); Mike Sapozhnikov, San Jose, CA (US); Yuqing Zhu, Shanghai (CN); Weiying Ding, Shanghai (CN); Yinxin Yang, Shanghai (CN); David Nozadze, San Jose, CA (US)

(21) Appl. No.: 18/810,930

(22) Filed: Aug. 21, 2024

Related U.S. Application Data
(60) Provisional application No. 63/570,428, filed on Mar. 27, 2024.

(51) Int. Cl. H05K 1/02; H05K 1/11

(52) U.S. Cl. CPC H05K 1/0228; H05K 1/113; H05K 2201/0707; H05K 2201/09227; H05K 2201/09518; H05K 2201/09527; H05K 2201/09609; H05K 2201/10189

(57) ABSTRACT

A PCB includes a unique fanout pattern that reduces cross-talk in a new way, and still enables the power routing into the connector of the PCB. Both signal integrity and power integrity performance meets the 224 Gbps requirement in terms of crosstalk, insertion loss, and return loss. In addition, the techniques disclosed herein improve on the density of the PCB and avoid the need for additional layer changing transition VIAs.

### CROSS-REFERENCE TO RELATED APPLICATION

This application is a non-provisional application of and claims the benefit of and priority to U.S. Patent App. No. 63/570,428, filed Mar. 27, 2024, entitled “PCB With Breakout to Enable Higher Density, Layer Count and Enhanced Performance,” the entire disclosure of which is incorporated by reference in its entirety.

### TECHNICAL FIELD

The present disclosure relates to circuit boards and, more particularly, to circuit boards that have improved performance characteristics.

### BACKGROUND

Conventional printed circuit board (PCB) manufacturing processes are unable to produce a PCB that meets the strict system performance requirements for a PCB including 102.4T ASICs with 512 SerDes and 224 Gbps per lane. The requirements result in huge challenges to signal integrity (SI) design. SI design to achieve best performance of insertion loss (IL), return loss (RL), and crosstalk is becoming exponentially challenging. In addition, power integrity (PI) is very difficult because power plane shapes are majorly reduced and/or completely broken with a large quantity of stitching VIAs required to optimize crosstalk performance.

For a next generation 102.4Tbps high density and high-power switch system, a front port configuration would be 64×1.6T, which is achieved by a 2×1 Belly-to-Belly stacked cage. In a Belly-to-Belly configuration, there are two connectors, one on the top of the PCB and one on the bottom of the PCB. In one implementation, top cage signals need to be routed in an upper half of a PCB, and bottom cage signals need to be routed in a lower half of a PCB. In this way, the top cage signal structures and the bottom cage signal structures do not overlap in the Z-axis, and crosstalk between the signals can be avoided. This results in a larger PCB that utilizes more material and has an increased cost.

Thus, there is a need for an improved signal structure that meets the desired IL, RL, and crosstalk performance requirements.

### BRIEF DESCRIPTION OF THE DRAWINGS

FIG. 1 is a schematic side view of an embodiment of a printed circuit board according to the techniques disclosed herein.

FIG. 2 is a plan view illustrating an outer layer of a PCB according to the techniques disclosed herein.

FIG. 3 is a bottom view illustrating another outer layer of a PBC according to the techniques disclosed herein.

FIG. 4 is a plan view of an intermediate layer of a PCB according to the techniques disclosed herein.

FIG. 5 is a plan view of an embodiment of a PCB showing multiple traces.

FIG. 6A is a top perspective view of signal pairs and VIAs of a PCB according to the techniques disclosed herein.

FIG. 6B is a top view of the signal pairs and VIAs illustrated in FIG. 6A.

FIG. 6C is a side view of the signal pairs and VIAs illustrated in FIG. 6A.

FIG. 7A is a graph illustrating OSFP 224 Gbps power-sum near end crosstalk lines for the different signal pairs illustrated in FIG. 6A.

FIG. 7B is a graph illustrating OSFP 224 Gbps power-sum far end crosstalk lines for the different signal pairs illustrated in FIG. 6A.

FIG. 8 is a top view of an OSFP 224 Gbps ground shape on a power layer of a PCB according to the techniques disclosed herein.

FIG. 9 is a top view of an OSFP 224 Gbps power shape on an external layer of a PCB according to the techniques disclosed herein.

FIGS. 10A, 10B, and 10C collectively are a schematic side view of an embodiment of a PCB according to the techniques disclosed herein.

FIG. 11A is a schematic view of an embodiment of a pin layout of a PCB according to the techniques disclosed herein.

FIG. 11B is a schematic plan view of a first or outermost layer of an embodiment of a PCB according to the techniques disclosed herein.

FIG. 11C is a schematic plan view of a second layer of an embodiment of a PCB according to the techniques disclosed herein.

FIG. 11D is a schematic plan view of a fourth layer of an embodiment of a PCB according to the techniques disclosed herein.

FIG. 11E is a schematic plan view of a forty-fourth or outermost layer of an embodiment of a PCB according to the techniques disclosed herein.

FIG. 11F is a schematic plan view of a forty-third layer of an embodiment of a PCB according to the techniques disclosed herein.

FIG. 11G is a schematic plan view of a forty-first layer of an embodiment of a PCB according to the techniques disclosed herein.

### DETAILED DESCRIPTION

### Overview

The problems with related art PCBs using a Belly-to-Belly stacked cage is the requirement that the top cage signal structures do not overlap with the bottom cage signal structures, which results in more layers needed for the PCB, and an increased overall size of the PCB.

For a 224 Gbps system, an ASIC ball grid array (BGA) design targets a power sum of near-end-crosstalk (PS-NEXT) below −55 dB and power sum of far-end-crosstalk (PS-FEXT) below −40 dB at 56 GHz. In addition, the PCB according to the techniques disclosed herein targets a RL of −15 dB at 56 GHz and keeps below −10 dB up to 75 GHz. For a 224 Gbps system, the quarter wavelength of 56 GHz (Nyquist frequency, if PAM4) is around 0.6 mm which means resonance needs to be addressed. To achieve sufficient shielding, the shielding VIAs pitch should be between ¼ to ⅛ of the wavelength. Conventional PCB design can only work when the data rate is slow enough or the pin pitch is small enough, both of which are very limiting.

For a next generation 102.4Tbps high density and high-power switch system, a front port configuration would be 64×1.6T, which is achieved by a 2×1 Belly-to-Belly stacked cage. For a cost-wise consideration, a pure PCB over cable solution can be used. This arrangement requires approximately a 44 layer stackup (six power layers and 14 high speed routing layers plus two miscellaneous routing layers), and one step high density interconnect (HDI) would be implemented as well. The board thickness reaches around 210 mil. There are many challenges for OSFP224 connector area high-speed SerDes trace fanout and power delivery. With the limited area SI performance, PCB manufacturing process, power delivery and thermal performance need to be addressed. Stitching VIAs are used as shielding ground vias in some cases, which will bring great benefits to crosstalk reduction. But in the same time, it will significantly degrade PI performance, additional stitching vias will bring extra void/opening on power plane (such as a large number of ground VIAs that cut up power planes), power planes with large cuts introduce micro cavity resonance with negative impact on crosstalk. In addition, more stitching VIAs will cause PCB manufacture issues that violate the distance requirement of VIA wall-to-wall and via-to-pad.

### Example Embodiments

According to the techniques disclosed herein, a PCB includes a unique fanout pattern that reduces cross-talk in a new way, and still enables the power routing into the connector of the PCB. Both signal integrity and power integrity performance meet the 224 Gbps requirement in terms of crosstalk, IL, and RL. In addition, the techniques disclosed herein improve on the density of the PCB and avoid the need for additional layer changing transition VIAs. Also, the techniques disclosed herein addresses the problems with one-step HDI technology, a short co-planar microstrip line on outer layers, and excellent high-speed VIA pattern. Routing layers can be allocated to allow for a Z-axis overlap for signal VIAs extending from a position proximate to an outer layer toward the opposite outer layer.

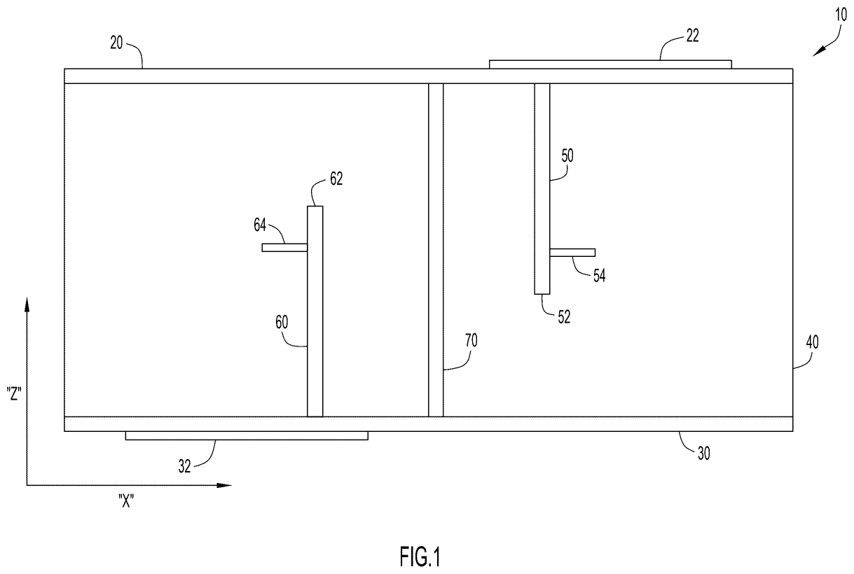

Referring to FIG. 1, a schematic side view of an embodiment of a PCB according to the techniques disclosed herein is illustrated. The PCB 10 has a top layer 20, a bottom layer 30 opposite the top layer 20, and several intermediate layers 40. In one embodiment, the PCB 10 has a top layer, a bottom layer 30, and 42 intermediate layers, which collectively form a 44 layer stack-up PCB. In FIG. 1, the relative axes showing different dimensional directions of the PCB 10, namely, an X-axis (in the width direction) and a Z-axis (in the vertical direction showing the thickness) are shown.

The PCB 10 has several of each of the following items, noting that only one of each of which is shown in the view illustrated in FIG. 1. The top layer 20 has several conductive traces 22 placed thereon. Similarly, the bottom layer 30 has several conductive traces 32 placed thereon. The PCB 10 includes several signal VIAs 50, such as high-speed signal VIAs, coupled to the conductive traces 22. Each VIA 50 has a distal end 52 and a signal trace 54 connected thereto, which signal trace 54 being located in the intermediate layers 40. The PCB 10 also includes several signal VIAs 60 that are high-speed signal VIAs coupled to conductive traces 32. Each VIA 60 has a distal end 62 and a signal trace 64 connected thereto.

In this embodiment, the PCB 10 includes several ground VIAs 70 that are located between the signal VIAs 50 and 60, which shield the signal VIAs 50 and 60 from each other. As shown in FIG. 1, the distal end 52 of each signal VIA 50 extends into the bottom or lower half of the PCB 10. Also, the distal end 62 of each signal VIA 60 extends into the top or upper half of the PCB 10. As a result, the distal ends 52 and 62 are located so that the signal VIAs 50 and 60 overlap with each other along the direction of arrow “Z”, and are not limited to only one half of the PCB 10. By providing the signal VIAs 50 and 60 so that they extend into the opposite half of the PCB 10, which enables a reduced quantity of layers of the PCB 10.

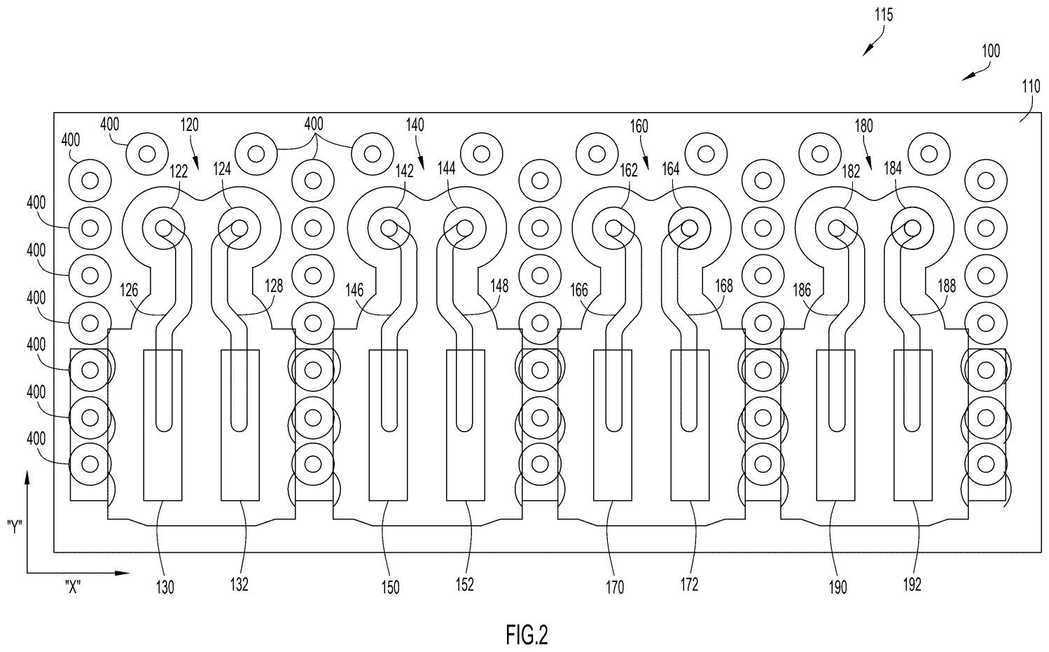

Turning to FIG. 2, a top or plan view of an embodiment of a fanout pattern of a top side cage on a top layer of a PCB is illustrated. Top layer 110 of PCB 100 includes a set of signal pairs 115, which includes four sets of signal pairs in this embodiment. In particular, the set of signal pairs 115 includes signal pair 120, signal pair 140, signal pair 160, and signal pair 180. Signal pair 120 includes signal VIAs 122 and 124, which are plating through hole (PTH) VIAs that extend from layer L1 to layer Ln. In one embodiment, PCB 100 has 44 layers, and n=44. Thus, the signal VIAs 122 and 124 extend from layer L1 to layer L44. Similarly, signal pair 140 includes signal VIAs 142 and 144, signal pair 160 includes signal VIAs 162 and 164, and signal pair 180 includes signal VIAs 182 and 184, each of which is a PTH VIA that extends from layer L1 to layer Ln. The top ends of each of the signal VIAs is illustrated in FIG. 2.

Signal VIAs 122 and 124 are connected to one end of microstrips 126 and 128, respectively, which in turn are connected to pads 130 and 132, respectively. The signal VIAs 122 and 124 fanout with the differential pair of microstrips or microstrip lines.

Signal VIAs 142 and 144 are connected to one end of microstrips 146 and 148, respectively, which in turn are connected to pads 150 and 152, respectively. Signal VIAs 162 and 164 are connected to one end of microstrips 166 and 168, respectively, which in turn are connected to pads 170 and 172, respectively. Signal VIAs 182 and 184 are connected to one end of microstrips 186 and 188, respectively, which in turn are connected to pads 190 and 192, respectively.

Also shown in FIG. 2 are ground VIAs 400, which are PTH VIAs that extend from layer L1 to layer Ln. In this view, the top ends of each of the ground VIAs 400 are illustrated. The ground VIAs 400 are located in substantially U-shaped arrangements on the outside of and between different signal pairs 120, 140, 160, and 180. For simplicity, not every one of the ground VIAs 400 is labeled with a reference number of 400. In FIG. 2, the axes showing different dimensional directions of the PCB 10, namely, an X-axis and a Y-axis, which relate to the X-axis and Z-axis shown in FIG. 1, are illustrated.

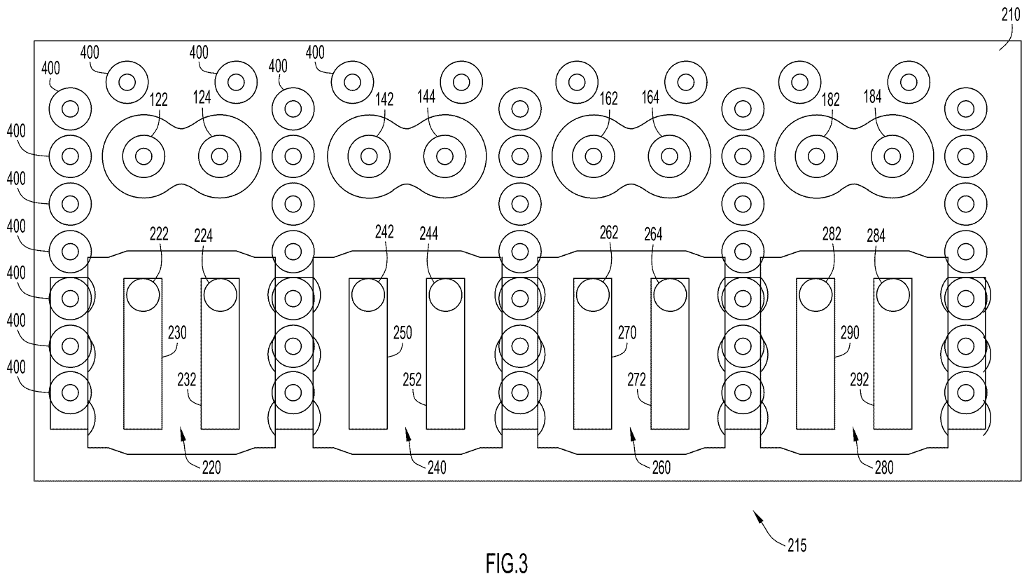

Turning to FIG. 3, a bottom view of a bottom side signal cage structure on a bottom layer of the PCB is illustrated. In this embodiment, the bottom side signal cage structure is a VIA in pad type structure, which involves placing a via directly under a surface-mount component pad, instead of placing the trace around the pad. For the bottom side OSFP connector high speed signals fanout, the bottom side signal cage structure includes several signal VIAs. Bottom layer 210 of PCB 100 includes a set of signal pairs 215, which includes four sets of signal pairs in this embodiment. In particular, the set of signal pairs 215 includes several pairs of signal VIAs, which include signal pair 220, signal pair 240, signal pair 260, and signal pair 280.

In particular, signal pair 220 includes signal VIAs 222 and 224, signal pair 240 includes signal VIAs 242 and 244, signal pair 260 includes signal VIAs 262 and 264, and signal pair 280 includes signal VIAs 282 and 284. Each of these signal VIAs 222, 224, 242, 244, 262, 264, 282, and 284 extend from layer Ln to Layer 2, and are combinations of (i) micro-VIAs extending from layer L n−1 to layer Ln; and (ii) PTH VIAs extending from layer L2 to layer L n−1. In an embodiment of PCB 100 that has 44 layers, the micro-VIAs extend from layer L43 to layer L44 (the bottom or exterior layer), and the PTH VIAs extend from layer L2 to layer L43.

In this embodiment, signal VIA 222 and signal VIA 224 are connected to pads 230 and 232, respectively. There is no fanout of any trace part relating to signal VIAs 222 and 224. Similarly, signal VIAs 242 and 244 are connected to pads 250 and 252, respectively. Also, signal VIAs 262 and 264 are connected to pads 270 and 272, respectively. In addition, signal VIAs 282 and 284 are connected to pads 290 and 292, respectively.

In FIG. 3, the bottom ends of the top cage signal VIAs 122, 124, 142, 144, 162, 164, 182, and 184 can be seen because they extend to layer Ln, which is illustrated. Also, the bottom ends of the ground VIAs 400 are also illustrated as they extend to layer Ln too.

In one embodiment, each of the signal VIAs 122, 124, 142, 144, 162, 164, 182, 184, 222, 224, 242, 244, 262, 264, 282, and 284 is backdrilled. It is to be understood that the top side signal cage structure illustrated in FIG. 2 as being on the top layer and the bottom side signal cage structure illustrated in FIG. 3 as being on the bottom layer can be switched so that the particular signal cage structures are located on the opposite outer layers of the PCB than those shown in FIGS. 2 and 3. In other words, instead of the fanout microstrips or microstrip lines on the top layer and the lack of them on the bottom layer, the fanout microstrips can be located on the bottom layer instead of the top layer.

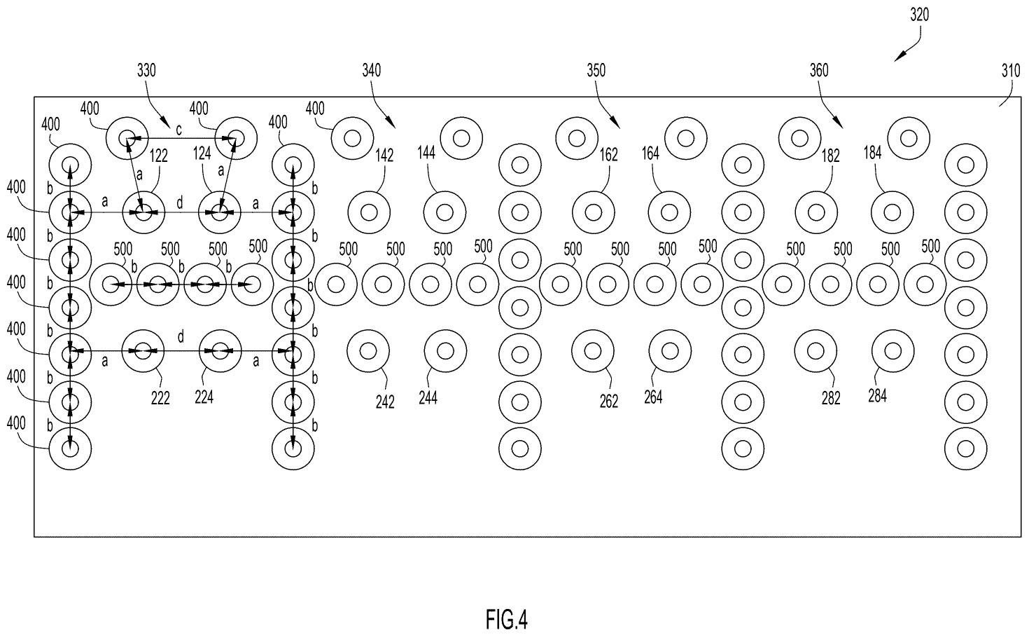

Turning to FIG. 4, a view of a portion of an inner layer or intermediate layer of the PCB 100 is illustrated. The fanout pattern is shown, along with several shielding ground VIAs 500 that are located between pairs of the signal VIAs extending from opposite outer layers of the PCB 100. No traces are shown in FIG. 4 for simplicity only.

For this portion of the intermediate layer 310, which is exemplary of the other intermediate layers, the intermediate layer 310 includes a set of VIAs 320, which includes several subsets of VIAs 330, 340, 350, and 360. VIA subset 330 includes signal VIAs 122 and 124, and signal VIAs 222 and 224, with several ground VIAs 500 (four in this embodiment), that are located between the signal VIAs 122 and 124 and the signal VIAs 222 and 224. The ground VIAs 500 isolate signal VIAs 122 and 124 from signal VIAs 142 and 144, which results in a reduced crosstalk level and meets 224 Gbps requirements.

Similarly, VIA subset 340 includes signal VIAs 142 and 144, and signal VIAs 242 and 244, with several ground VIAs 500 therebetween as shown. Also, VIA subset 350 includes signal VIAs 162 and 164, and signal VIAs 262 and 264, with several ground VIAs 500 therebetween. In addition, VIA subset 360 includes signal VIAs 182 and 184, and signal VIAs 282 and 284, with several ground VIAs 500 therebetween. In this embodiment, ground VIAs 400 are located around the different subsets of VIAs. The spaces between the VIAs are sufficient for internal traces to go out.

In one embodiment, each shielding ground VIA 500 are PTH VIAs that extend from layer L2 to Layer L n−1. In the PCB 100 with 44 layers, the ground VIAs 500 extend from layer L2 to layer L43. By not extending the ground VIAs 500 to layer L1 and layer Ln, that allows for trace signals to travel freely in layer L1 and layer Ln.

For the end-to-end link (OSFP←→Host ASIC), additional transition VIA(s) for avoiding crosstalk at a host ASIC BGA area are not needed. The following Table 1 provides the detailed VIA locations that are critical to provide good signal integrity performance with respect to crosstalk, IL, and RL.

TABLE 1

| Identification in FIG. 4 | Dimension | Value (mil) |
|---|---|---|
| a | Signal to GND pitch | 23.622 |
| b | GND to GND pitch | 15 |
| c | GND to GND pitch | 35.052 |
| d | Signal to Signal pitch | 23.622 |

The unique pattern disclosed herein ensures that high-density stacked B2B OSFP high-speed signals fanout routing at limited connector areas with excellent SI and PI performance.

FIGS. 2-4 relate to the same portion of different layers in a PCB 100, and each illustrates the same view of the various signal VIAs.

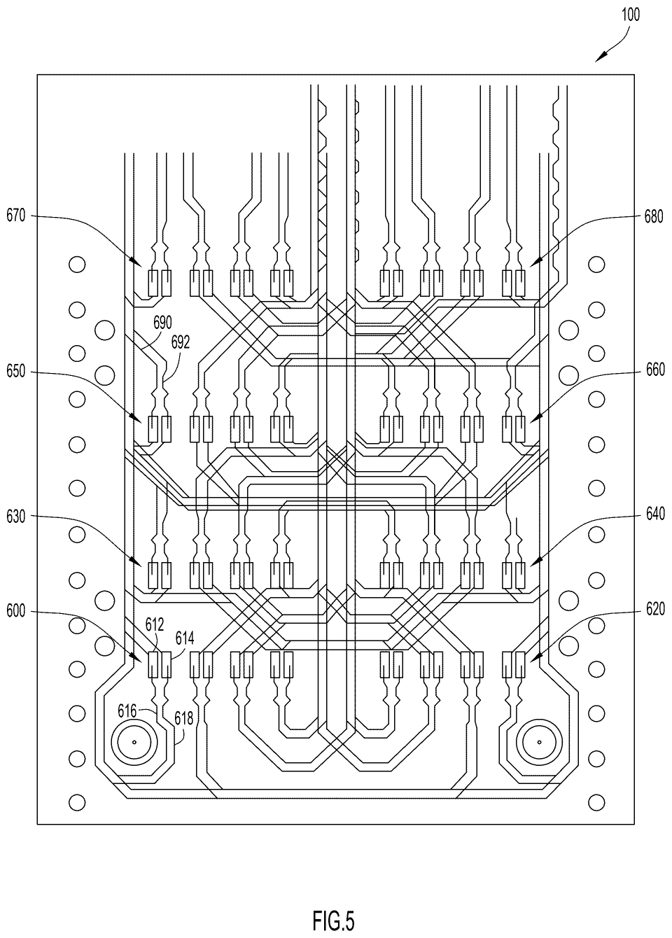

Referring to FIG. 5, the high speed digital (HSD) routings at a connector area are illustrated. In this view, both the traces for the top side OSFP ports and the traces for the bottom side OSFP ports are illustrated. The differential pairs from the top layer and the bottom layer can be fanned out as shown. The conductive traces are oriented toward an ASIC, which is not shown in FIG. 5.

Also, the signal VIAs and trace pattern shown in FIGS. 2-4 is repeated on this layer for form eight different sets. As shown, there are eight signal VIA sets 600, 620, 630, 640, 650, 660, 670, and 680, each of which has the same structure as the other sets. Signal VIA set 600 includes a pair of top signal VIAs (not shown) that are connected to pads 612 614, which are connected to inner-layer traces 616 and 618, respectively. Also shown in FIG. 5 are several of the inner-layer signal traces connected to bottom connector pads, such as traces 690 and 692.

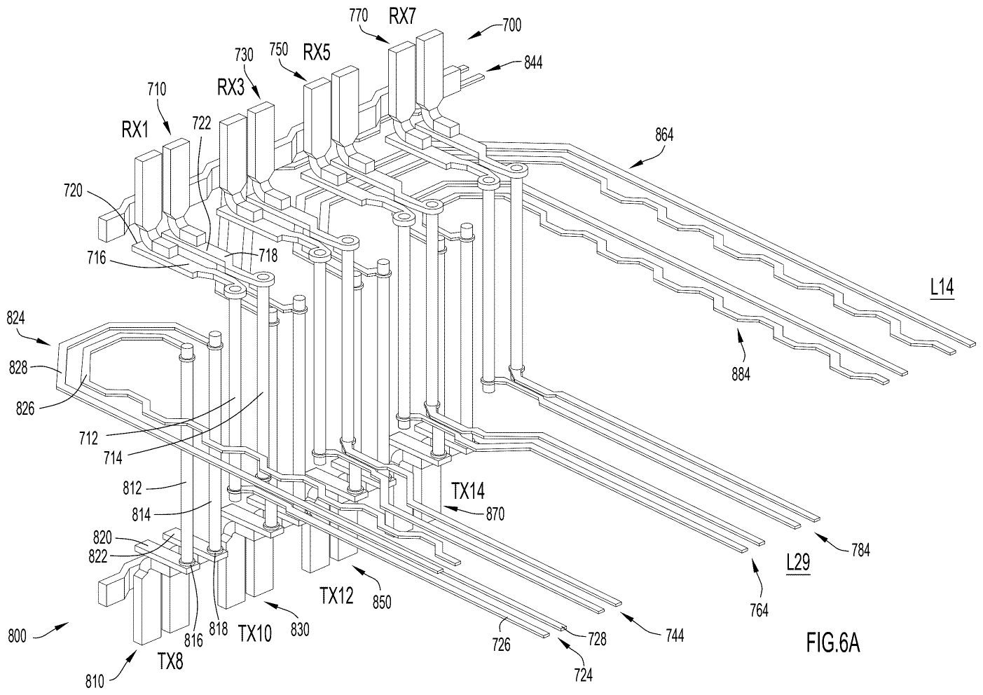

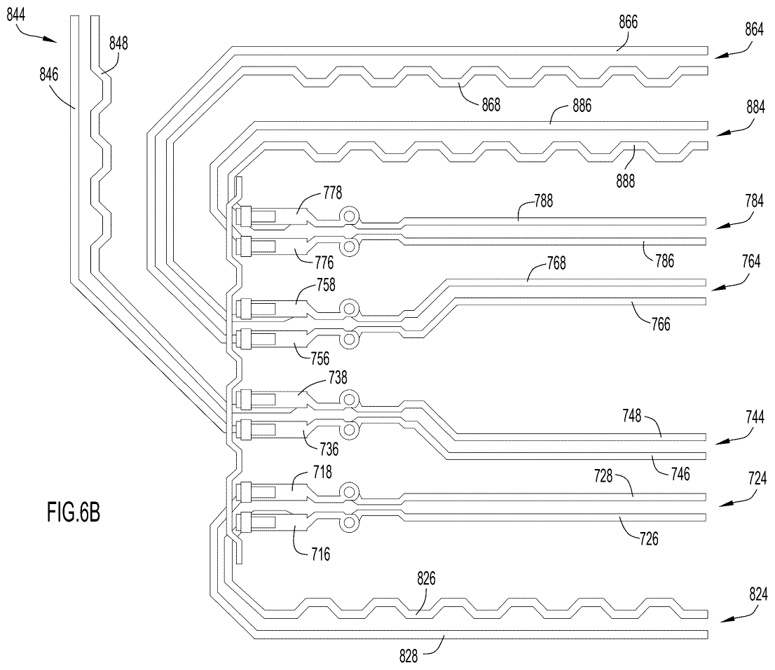

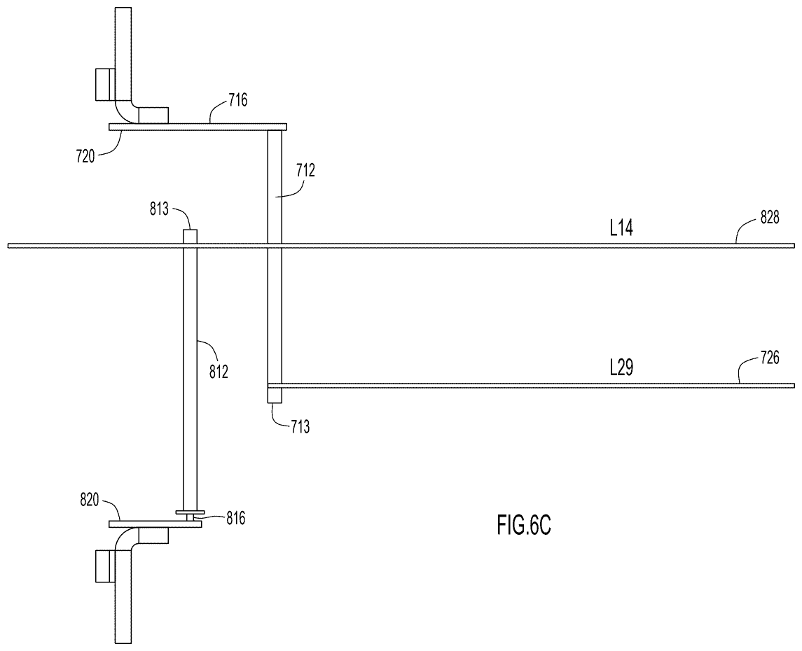

Turning to FIGS. 6A and 6B, a top perspective view and a top view of a signal path are illustrated, respectively. It is to be appreciated that the view illustrated in FIG. 6A shows the Z-axis overlap of the top side signal VIAs and the bottom side signal VIAs. Top traces 700 include signal pairs 710, 730, 750, and 770. Signal pair 710 includes a pair of pads 720 and 722, which are connected to microstrips 716, and 718, respectively. The microstrips 716 and 718 are connected to the upper ends of signal VIAs 712 and 714, respectively. Coupled proximate to the lower ends of signal VIAs 712 and 714 are a set of traces 724, which includes traces 726 and 728. It is understood that the traces 726 and 728 continue on beyond the ends shown.

Similarly, signal pair 730 includes a pair of pads, which includes pads connected to microstrips 736 and 738. The microstrips 736 and 738 are connected to the upper ends of signal VIAs. Coupled proximate to the lower ends of the signal VIAs are a set of traces 744, which includes traces 746 and 748. Signal pair 750 includes a pair of pads, which includes pads connected to microstrips 756 and 758. The microstrips 756 and 758 are connected to the upper ends of signal VIAs. Coupled proximate to the lower ends of the signal VIAs are a set of traces 764, which includes traces 766 and 768. Also, signal pair 770 includes a pair of pads, which includes pads connected to microstrips 776 and 778. The microstrips 776 and 778 are connected to the upper ends of signal VIAs. Coupled proximate to the lower ends of the signal VIAs are a set of traces 784, which includes traces 786 and 788.

Bottom traces 800 include signal pairs 810, 830, 850, and 870. Signal pair 810 includes a pair of pads 820 and 822, to which micro-VIAs 816 and 818 are connected, respectively. The signal VIAs 812 and 814 are connected to the micro-VIAs 816 and 818, respectively. Coupled proximate to the upper ends of signal VIAs 812 and 814 is a set of traces 824, which includes traces 826 and 828. It is understood that the traces 826 and 828 continue beyond the ends shown.

Signal pair 830 includes a pair of pads to which micro-VIAs are connected, and signal VIAs are connected to the micro-VIAs. Coupled proximate to the upper ends of signal VIAs are a set of traces 844, which includes traces 846 and 848. Similarly, signal pair 850 includes a pair of pads to which micro-VIAs are connected, and signal VIAs are connected to the micro-VIAs. Coupled proximate to the upper ends of signal VIAs are a set of traces 864, which includes traces 866 and 868. Signal pair 870 includes a pair of pads to which micro-VIAs are connected, and signal VIAs are connected to the micro-VIAs. Coupled proximate to the upper ends of signal VIAs are a set of traces 884, which includes traces 886 and 888. It is understood that the traces 846, 848, 866, 868, 886, and 888 continue beyond the ends shown in FIG. 6B.

Referring to FIG. 6C, a side view of the signal structure illustrated in FIGS. 6A and 6B is shown. In this view, for the top signal structure, the pad 720, the microstrip 716, and the signal VIA 712 are shown. Trace 726, which in this embodiment is located at layer L29 in the PCB 100, is shown connected to the signal VIA 712 proximate to its distal end 713. For the bottom signal structure, the pad 820 is shown connected to the micro-VIA 816 to which the signal VIA 812 is connected. A trace 828 is connected to the signal VIA 812 proximate to its distal end 813. As shown, the distal end 713 of signal VIA 712 is located below the distal end 813 of signal VIA 812 along the Z-axis. The signal VIAs 712 and 812 are overlapping along the Z-axis. This design is different from other PCBs in that the signal VIAs 712 and 812 are not limited to a particular half of the PCB. Not shown in FIG. 6C are the shielding ground VIAs that isolate signal VIA 712 from signal VIA 812, thereby allowing them to overlap while maintaining SI integrity and PI integrity levels.

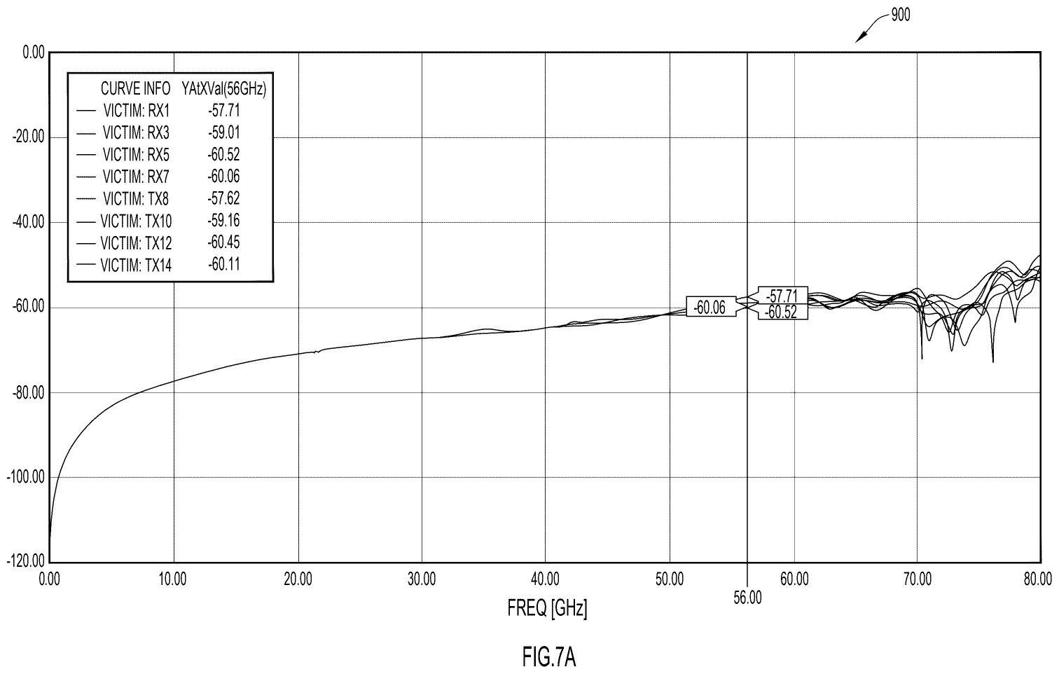

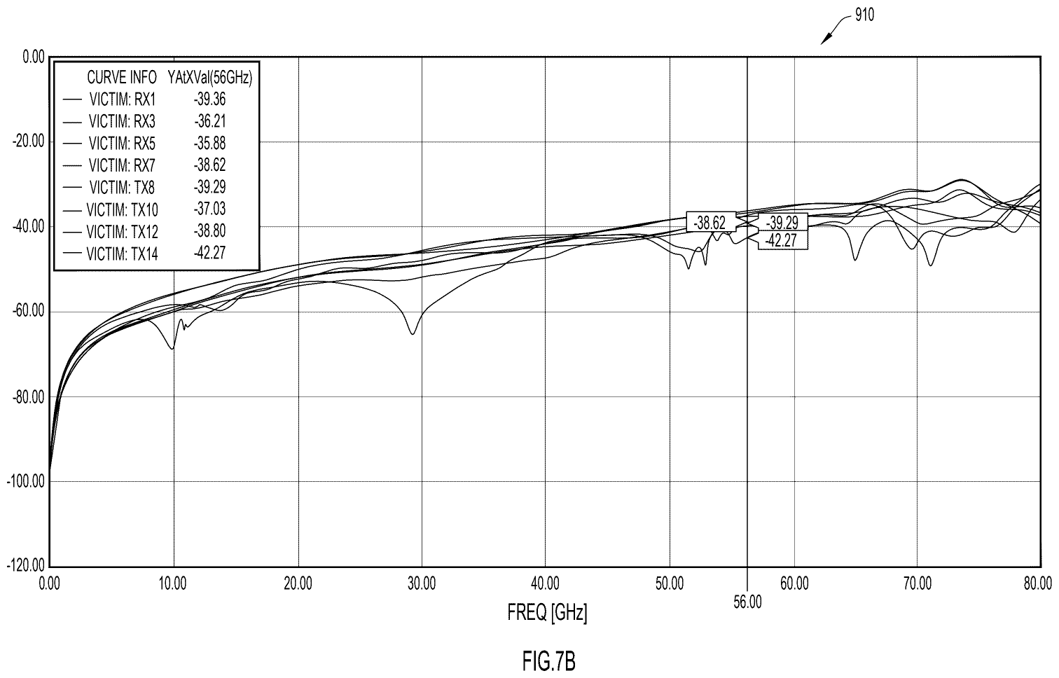

A PCB according to the techniques disclosed herein accomplishes the near-end crosstalk (NEXT) and the far-end crosstalk (FEXT) results that are illustrated in the graphs shown in FIGS. 7A and 7B, respectively. In FIG. 7A, the graph 900 shows the results in the power-sum NEXT data are based 4 aggressors, −57 dB at 56 GHz. In FIG. 7B, the graph 910 shows the results in the power-sum FEXT data are based on 3 aggressors, −35 dB at 56 GHz.

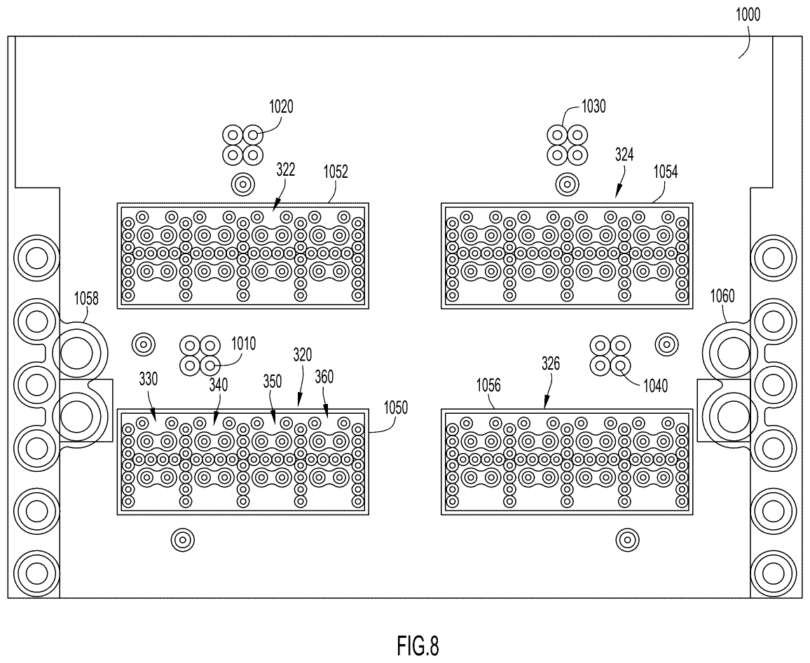

Turning to FIG. 8, a plan view of an embodiment of a power plane shape or power shape is illustrated. To avoid and reduce cavity resonance in a power layer, which could be created due to a void inside the power shape, a ground plane is added inside the power shape as disclosed herein. For an OSFP 224 Gbps design, a current path is needed for each power rail. A fanout pattern leaves enough space for the power plane, which has a large part of the power plane available for internal layer power distribution.

In this embodiment, the power shape or power plane 1000, which is an intermediate layer, has great integrity and a reduced quantity of breakups or interruptions, which improves the PI of the power plane 1000. In FIG. 8, there are several groups of power VIAs, which are grouped together to reduce the quantity of openings in the power plane 1000. Each VIA in the groups of power VIAs 1010 and 1020 includes four VIAs that is connected to this power plane 1000. The PCB 100 also includes two other groups of power VIAs 1030 and 1040 that are connected a different power plane in the PCB 100.

The power plane 1000 has openings 1050, 1052, 1054, and 1056 formed therein, which are referred to alternatively as ground shapes. In this embodiment, the PCB 100 has grouped the different sets of VIAs into clusters close to each other to reduce the quantities of the openings in the power plane 1000. As shown, the signal VIAs are arranged into VIA sets 320, 322, 324, and 326, which are located in openings 1050, 1052, 1054, and 1056, respectively. As described above relative to FIG. 4, the VIA set 320 includes VIA subsets 330, 340, 350, and 360. The other VIA sets 322, 324, and 326 are structured similarly to VIA set 320. The power plane 1000 also includes a few additional openings, such as openings 1058 and 1060.

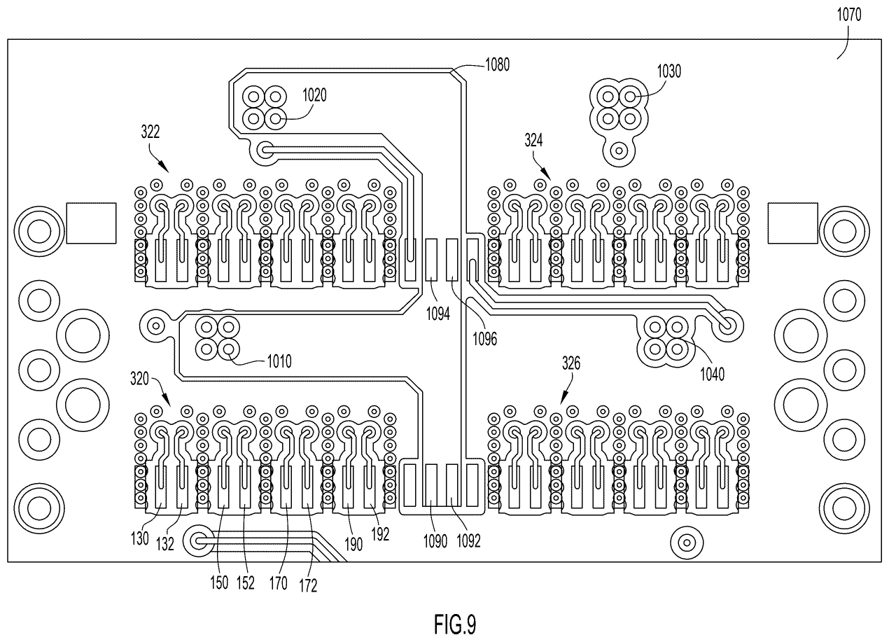

Referring to FIG. 9, an embodiment of an external layer power shape is shown. This power shape embodiment results in improved power performance. As a result, even with stacked 2×1 OSFP Bell-to-Belly cage structure, the direct current (DC) loss of each rail is less than one percent routed on four 2 ounce power layers together with external layers power routing.

Outer layer 1070, which includes signal structures similar to those on top layer 110 illustrated in FIG. 2. To minimize the extent of outer layer 1070 used for power, the boundary 1080 of the power section includes groups of power VIAs 1010 and 1020 located therein. The outer layer 1070 includes two groups of power pins. Power pins 1090 and 1092 are located proximate to each other, and power pins 1094 and 1096 are located proximate to each other as well. In this embodiment, the power VIAs 1010 and 1020 are fanned out and positioned away from the power pins 1090, 1092, 1094, and 1096. For the top connector, the relevant power VIAs 1010 and 1020 are fanned out to the left in FIG. 9. For the bottom connector, the relevant power VIAs 1030 and 1040 are fanned out to the right in FIG. 9.

An advantage of this fanout arrangement of the power VIAs is that there are no power VIAs located in the middle of the PCB, which provides sufficient room for the high speed traces to be located easily in the area. Another advantage of this power VIA fanout arrangement is an improved power plane integrity in the middle region of the PCB due to the reduced quantity of openings or breaks in the power plane.

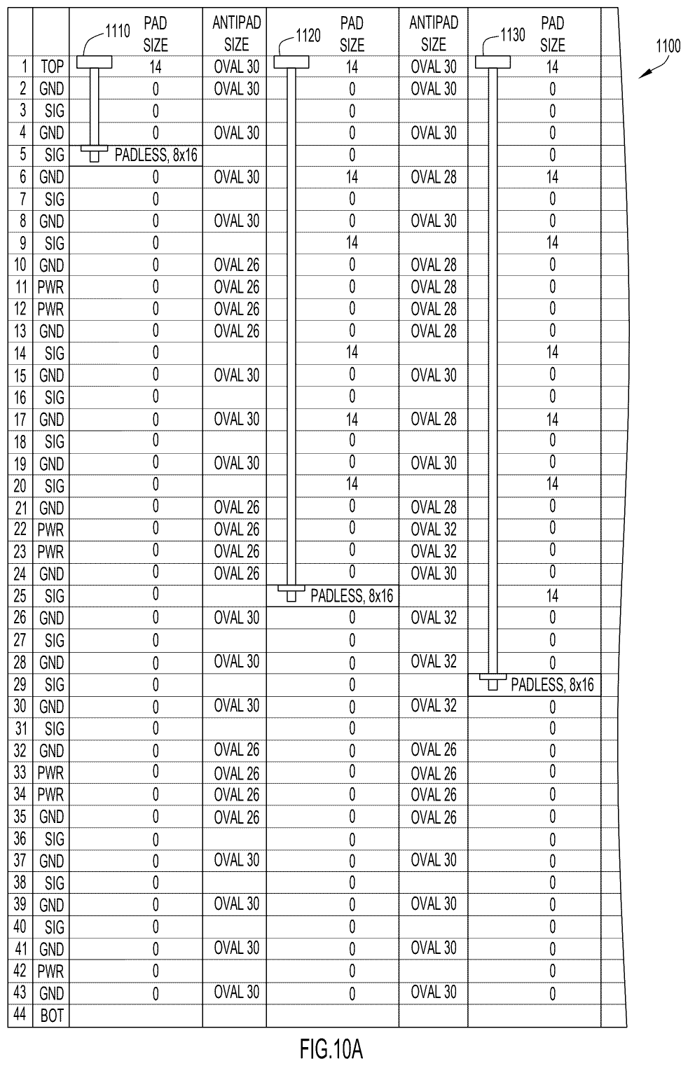

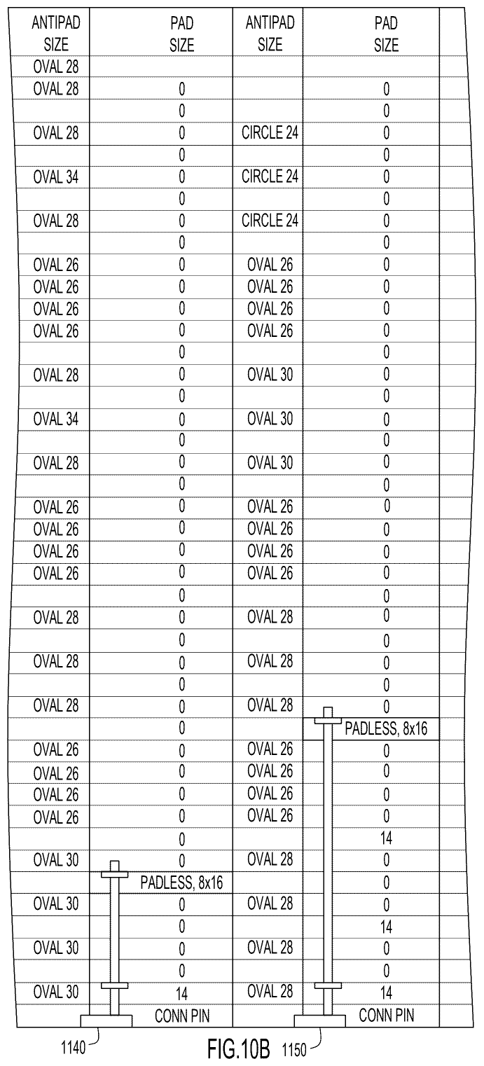

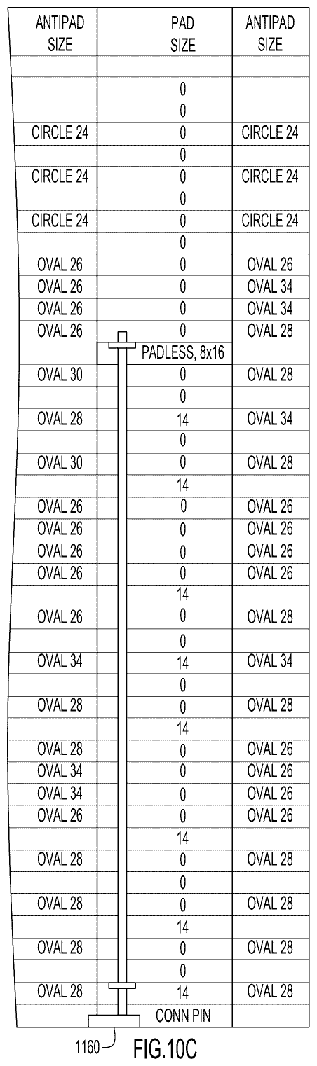

Turning to FIGS. 10A, 10B, and 10C, a schematic view of an embodiment of a PCB 1100 is illustrated. In this embodiment, the PCB 1100 includes 44 layers which include top signal VIAs 1110, 1120, and 1130, each of which has a different length. Signal VIA 1110 extends from layer L1 to layer L5. Signal VIA 1120 extends from layer L1 to layer L25. Signal VIA 1130 extends from layer L1 to layer L29.

The PCB 100 also includes bottom signal VIAs 1140, 1150, and 1160, each of which has a different length as well. Signal VIA 1140 extends from layer L44 to layer L38. Signal VIA 1150 extends from layer L44 to layer L31. Signal VIA 1160 extends from layer L44 to layer L14. Some exemplary dimensions relating to PCB 1100 are set forth in the following Table 2.

TABLE 2

| Signal Top Layer | Top | Top | Top | Bottom | Bottom | Bottom |
|---|---|---|---|---|---|---|
| Signal Bottom Layer | 5 | 25 | 29 | 38 | 31 | 14 |
| Drill Diameter (mil) | 7.9 | 7.9 | 7.9 | 7.9 | 7.9 | 7.9 |
| Finish Hole Size (mil) | 6 | 6 | 6 | 6 | 6 | 6 |

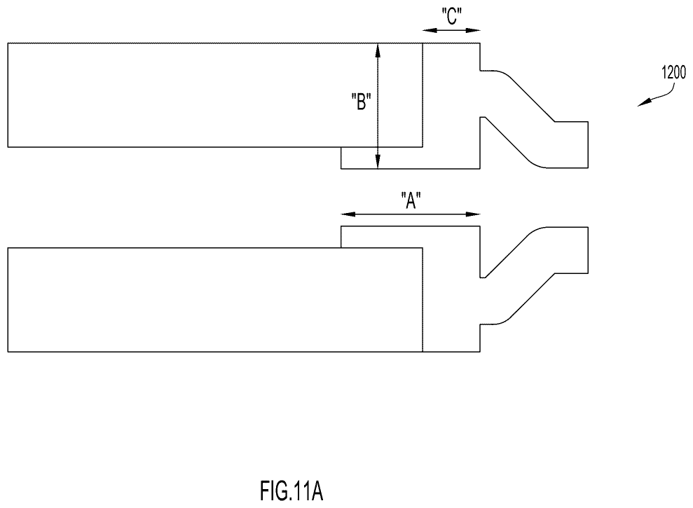

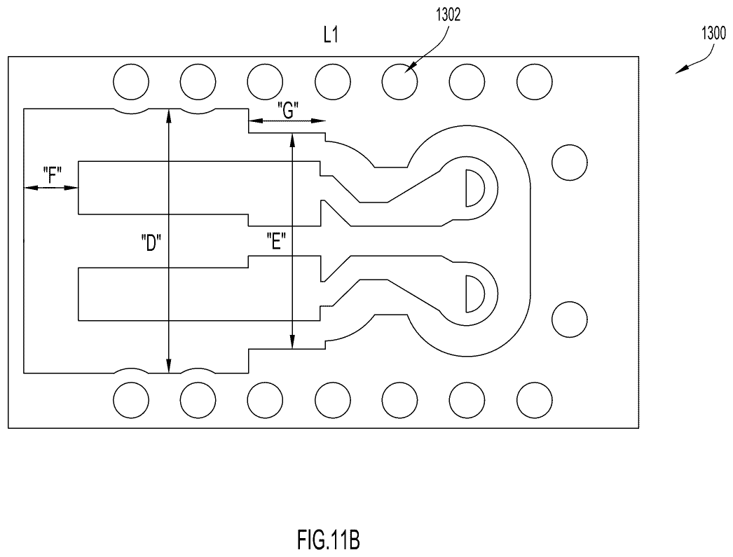

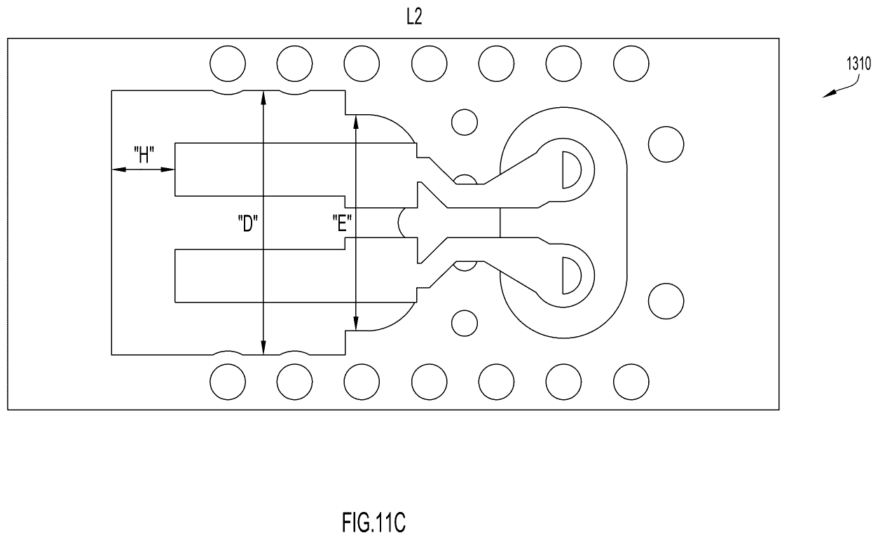

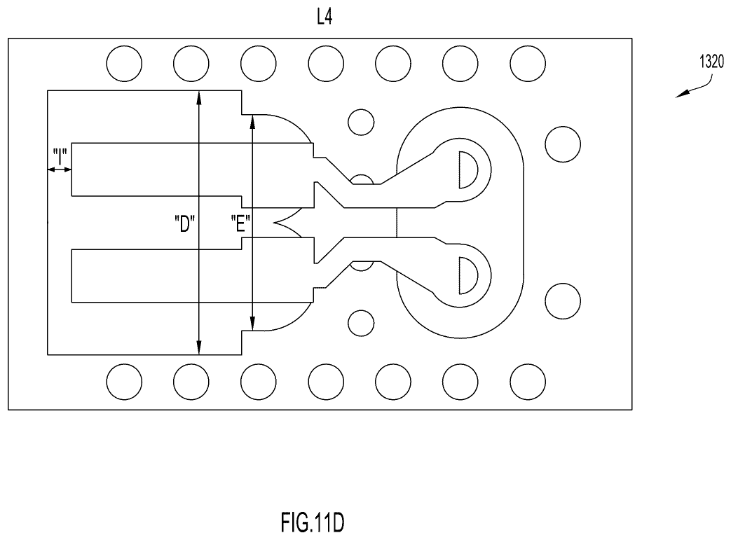

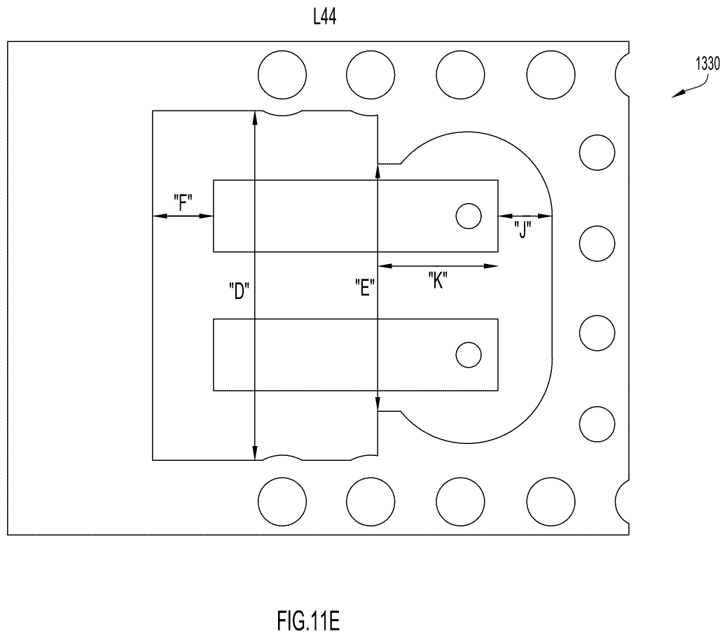

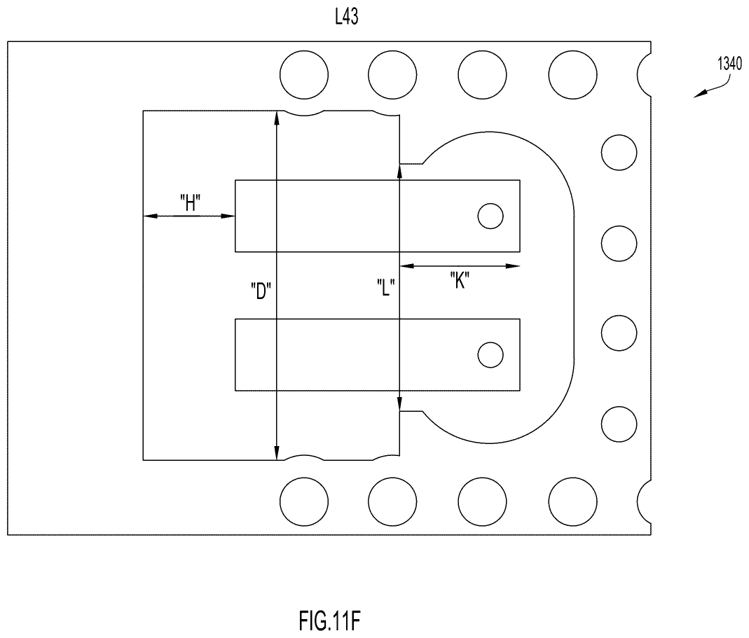

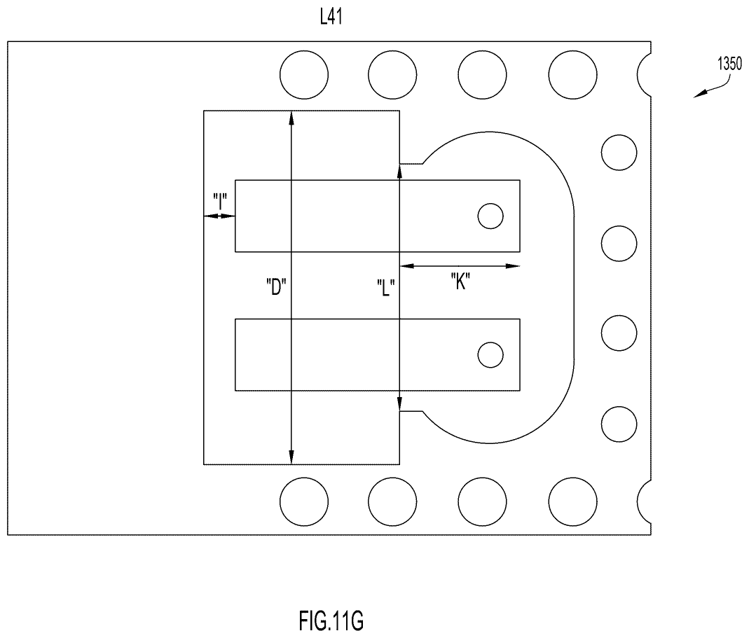

Turning to FIGS. 11A-11G, schematic diagrams of a pin layout and PCB layers are illustrated. Referring to FIG. 11A, an exemplary pin layout 1200 is shown. In one exemplary embodiment, dimension “A” is 16 mil, dimension “B” is 14.5 mil, and dimension “C” is 6 mil.

In FIGS. 11B-11D, microstrips are illustrated in each of these layers located near the top of the PCB. Referring to FIG. 11B, a plan view of a pattern of layer L1 is illustrated. In this layer 1300, holes 1302 are formed for the ground VIAs 400. The microstrips and pads are illustrated in this view. Dimension “D” is 58.526 mil, dimension “E” is 48.622 mil, dimension “F” is 12 mil, and dimension “G” is 16 mil. Layer 1310 is layer L2 and has some similar dimensions, which are dimensions “D” and “E”. In this embodiment, dimension “H” is 15 mil. Layer 1320 is layer LA in the PCB and has similar dimensions “D” and “E”. Dimension “I” is 5 mil, which results in the pads being close to edge of the opening in which they are located.

In FIGS. 11E-11G, there are pads and no microstrips illustrated in each of these layers located near the bottom of the PCB. Referring to FIG. 11E, a plan view of a pattern of layer L44 is illustrated. In this layer 1330, dimensions “D”, “E”, and “F” are the same as the previous layers. Dimension “J” is 9.9 mil and dimension “K” is 20 mil. Layer 1340 is layer L43 and has some similar dimensions, which are dimensions “D”, “H”, and “K”. In this layer 1340, dimension “L” is 41.622 mil. Layer 1350 is layer L41 in the PCB and has similar dimensions “D”, “I”, and “K”. Dimension “I” is 5 mil, which results in the pads being close to edge of the opening in which they are located

The techniques disclosed herein provide several advantages, which include at least the following features. One advantage is guaranteed excellent SI performance with a good strategy to eliminate micro-cavity resonance on a power plane. Electromagnetic interference (EMI) performance is good as well with a co-planar structure used on outer layers of a PCB. Another advantage is sufficient space for outer and inner layer traces to connect to VIAs at limited OSFP connector areas. Another advantage allows all 16 high-speed differential pairs of signals of one row (top and bottom) to fanout in the constrained space between adjacent two rows of an OSFP pin area. An additional advantage is a low cost with good SI performance solution for a 224 Gbps high density system. Removing the majority of the transition VIAs that might be required with a traditional implementation reduces the overall material and the overall cost. Another advantage is excellent PI, with improved thermal performance with more power shape available and useable at OSFP connector area. Finally, another advantage is no additional effort for an eCAD engineer and consistent design for manufacturability (DFM)/design for assembly (DFA) rules.

In one embodiment, the compact fanout pattern can: 1) tolerate Z-axis overlap, which reduces high speed layer count, and decreases the usage of layer transition vias; and 2) reduce power plane cuts, which provides decent power delivery with limited power layers. In addition to a reduced overall PCB cost, the manufacture reliability is robust, and the overall SI/PI performance is improved.

In some aspects, the techniques described herein relate to a printed circuit board, comprising a top layer with a first conductive trace, a bottom layer with a second conductive trace, a first signal VIA connected to the first conductive trace, and a second signal VIA connected to the second conductive trace, wherein a portion of the first signal VIA overlaps a portion of the second signal VIA along a Z-axis of the printed circuit board.

In some aspects, the techniques described herein relate to a printed circuit board including a ground VIA extending from the top layer to the bottom layer, and the ground VIA is located between the first signal VIA and the second signal VIA.

In some aspects, the techniques described herein relate to the first signal VIA having a first distal end, the second signal VIA has a second distal end, a distance between the first distal end of the first signal VIA and the bottom layer is a first distance, a distance between the second distal end of the second signal VIA and the bottom layer is a second distance, and the first distance is less than the second distance.

In some aspects, the techniques described herein relate to the top layer having a top side cage signal structure that has a fanout pattern.

In some aspects, the techniques described herein relate to a printed circuit board, further comprising a first microstrip having a first end and a second end, and a pad, wherein the first signal VIA is connected to the first end of the first microstrip, and the second end of the first microstrip is connected to the pad.

In some aspects, the techniques described herein relate to a printed circuit board, further comprising a second microstrip, wherein the first microstrip and second microstrip are arranged in a fanout pattern.

In some aspects, the techniques described herein relate to the bottom side signal cage structure on the bottom layer having a VIA in pad type structure.

In some aspects, the techniques described herein relate to a printed circuit board, comprising a plurality of layers including ground layers, signal layers, a top layer, and a bottom layer, the top layer having a first conductive trace, and the bottom layer having a second conductive trace, a first signal VIA extending through several layers of the plurality of layers, the first signal VIA being connected to the first conductive trace, the first signal VIA having a first distal end, and a second signal VIA extending through several layers of the plurality of layers, the second signal VIA being connected to the second conductive trace, the second signal VIA having a second distal end, wherein the first distal end of the first signal VIA is closer to the bottom layer than the second distal end of the second signal VIA.

In some aspects, the techniques described herein relate to a portion of the first signal VIA overlapping a portion of the second signal VIA along a Z-axis of the printed circuit board.

In some aspects, the techniques described herein relate to the distance between the first distal end of the first signal VIA and the top layer being a first distance, a distance between the second distal end of the second signal VIA and the top layer is a second distance, and the first distance is greater than the second distance.

In some aspects, the techniques described herein relate to the printed circuit board including a ground VIA extending from the top layer to the bottom layer, and the ground VIA is located between the first signal VIA and the second signal VIA.

In some aspects, the techniques described herein relate to the top layer having a top side cage signal structure that has a fanout pattern.

In some aspects, the techniques described herein relate to a printed circuit board, further comprising a first microstrip having a first end and a second end, and a pad, wherein the first signal VIA is connected to the first end of the first microstrip, and the second end of the first microstrip is connected to the pad.

In some aspects, the techniques described herein relate to a printed circuit board, further comprising a second microstrip, wherein the first microstrip and second microstrip are arranged in a fanout pattern.

In some aspects, the techniques described herein relate to a printed circuit board, comprising a plurality of layers, including ground layers, signal layers, a top layer, and a bottom layer, the top layer having a first conductive trace, and the bottom layer having a second conductive trace, a first signal VIA extending through several layers of the plurality of layers, the first signal VIA being connected to the first conductive trace, the first signal VIA having a first distal end, a second signal VIA extending through several layers of the plurality of layers, the second signal VIA being connected to the second conductive trace, the second signal VIA having a second distal end, and a ground VIA extending through several layers of the plurality of layers, the ground VIA being located between the first signal VIA and the second signal VIA, wherein a distance between the first distal end and the bottom layer is a first distance, a distance between the second distal end and the bottom layer is a second distance, and the first distance is less than the second distance.

In some aspects, the techniques described herein relate to a portion of the first signal VIA overlapping a portion of the second signal VIA along a Z-axis of the printed circuit board.

In some aspects, the techniques described herein relate to the top layer having a top side cage signal structure that has a fanout pattern.

In some aspects, the techniques described herein relate to a printed circuit board, further comprising a first microstrip having a first end and a second end, and a pad, wherein the first signal VIA is connected to the first end of the first microstrip, and the second end of the first microstrip is connected to the pad.

In some aspects, the techniques described herein relate to a printed circuit board, further comprising a second microstrip, wherein the first microstrip and second microstrip are arranged in a fanout pattern.

In some aspects, the techniques described herein relate to a bottom side signal cage structure on the bottom layer having a VIA in pad type structure.

### Variations and Implementations

Note that in this specification, references to various features (e.g., elements, structures, nodes, modules, components, engines, logic, steps, operations, functions, characteristics, etc.) included in “one embodiment,” “example embodiment,” “an embodiment,” “another embodiment,” “certain embodiments,” “some embodiments,” “various embodiments,” “other embodiments,” “alternative embodiment,” and the like are intended to mean that any such features are included in one or more embodiments of the present disclosure, but may or may not necessarily be combined in the same embodiments.

It is also noted that the operations and steps described with reference to the preceding figures illustrate only some of the possible scenarios that may be executed by one or more entities discussed herein. Some of these operations may be deleted or removed where appropriate, or these steps may be modified or changed considerably without departing from the scope of the presented concepts. In addition, the timing and sequence of these operations may be altered considerably and still achieve the results taught in this disclosure. The preceding operational flows have been offered for purposes of example and discussion. Substantial flexibility is provided by the embodiments in that any suitable arrangements, chronologies, configurations, and timing mechanisms may be provided without departing from the teachings of the discussed concepts.

As used herein, unless expressly stated to the contrary, use of the phrase “at least one of,” “one or more of,” “and/or,” variations thereof, or the like are open-ended expressions that are both conjunctive and disjunctive in operation for any and all possible combination of the associated listed items. For example, each of the expressions “at least one of X, Y and Z,” “at least one of X, Y or Z,” “one or more of X, Y and Z,” “one or more of X, Y or Z” and “X, Y and/or Z” can mean any of the following: 1) X, but not Y and not Z; 2) Y, but not X and not Z; 3) Z, but not X and not Y; 4) X and Y, but not Z; 5) X and Z, but not Y; 6) Y and Z, but not X; or 7) X, Y, and Z.

Each example embodiment disclosed herein has been included to present one or more different features. However, all disclosed example embodiments are designed to work together as part of a single larger system or method. This disclosure explicitly envisions compound embodiments that combine multiple previously-discussed features in different example embodiments into a single system or method.

Additionally, unless expressly stated to the contrary, the terms “first,” “second,” “third,” etc., are intended to distinguish the particular nouns they modify (e.g., element, condition, node, module, activity, operation, etc.). Unless expressly stated to the contrary, the use of these terms is not intended to indicate any type of order, rank, importance, temporal sequence, or hierarchy of the modified noun. For example, “first X” and “second X” are intended to designate two “X” elements that are not necessarily limited by any order, rank, importance, temporal sequence, or hierarchy of the two elements. Further as referred to herein, “at least one of” and “one or more of” can be represented using the “(s)” nomenclature (e.g., one or more element(s)).

The above description is intended by way of example only. Although the techniques are illustrated and described herein as embodied in one or more specific examples, it is nevertheless not intended to be limited to the details shown, since various modifications and structural changes may be made within the scope and range of equivalents of the claims.

What is claimed is:

1. A printed circuit board, comprising:
a top layer with a first conductive trace;
a bottom layer with a second conductive trace;
a first signal VIA connected to the first conductive trace; and
a second signal VIA connected to the second conductive trace, wherein a portion of the first signal VIA overlaps a portion of the second signal VIA along a Z-axis of the printed circuit board.

2. The printed circuit board of claim 1, wherein the printed circuit board includes a ground VIA extending from the top layer to the bottom layer, and the ground VIA is located between the first signal VIA and the second signal VIA.

3. The printed circuit board of claim 1, wherein the first signal VIA has a first distal end, the second signal VIA has a second distal end, a distance between the first distal end of the first signal VIA and the bottom layer is a first distance, a distance between the second distal end of the second signal VIA and the bottom layer is a second distance, and the first distance is less than the second distance.

4. The printed circuit board of claim 1, wherein the top layer has a top side cage signal structure that has a fanout pattern.

5. The printed circuit board of claim 1, further comprising:
a first microstrip having a first end and a second end; and
a pad, wherein the first signal VIA is connected to the first end of the first microstrip, and the second end of the first microstrip is connected to the pad.

6. The printed circuit board of claim 5, further comprising:
a second microstrip, wherein the first microstrip and second microstrip are arranged in a fanout pattern.

7. The printed circuit board of claim 1, wherein a bottom side signal cage structure on the bottom layer has a VIA in pad type structure.

8. A printed circuit board, comprising:
a plurality of layers including ground layers, signal layers, a top layer, and a bottom layer, the top layer having a first conductive trace, and the bottom layer having a second conductive trace;
a first signal VIA extending through several layers of the plurality of layers, the first signal VIA being connected to the first conductive trace, the first signal VIA having a first distal end; and
a second signal VIA extending through several layers of the plurality of layers, the second signal VIA being connected to the second conductive trace, the second signal VIA having a second distal end, wherein the first distal end of the first signal VIA is closer to the bottom layer than the second distal end of the second signal VIA.

9. The printed circuit board of claim 8, wherein a portion of the first signal VIA overlaps a portion of the second signal VIA along a Z-axis of the printed circuit board.

10. The printed circuit board of claim 8, wherein a distance between the first distal end of the first signal VIA and the top layer is a first distance, a distance between the second distal end of the second signal VIA and the top layer is a second distance, and the first distance is greater than the second distance.

11. The printed circuit board of claim 10, wherein the printed circuit board includes a ground VIA extending from the top layer to the bottom layer, and the ground VIA is located between the first signal VIA and the second signal VIA.

12. The printed circuit board of claim 8, wherein the top layer has a top side cage signal structure that has a fanout pattern.

13. The printed circuit board of claim 12, further comprising:
a first microstrip having a first end and a second end; and
a pad, wherein the first signal VIA is connected to the first end of the first microstrip, and the second end of the first microstrip is connected to the pad.

14. The printed circuit board of claim 13, further comprising:
a second microstrip, wherein the first microstrip and second microstrip are arranged in a fanout pattern.

15. A printed circuit board, comprising:
a plurality of layers, including ground layers, signal layers, a top layer, and a bottom layer, the top layer having a first conductive trace, and the bottom layer having a second conductive trace;
a first signal VIA extending through several layers of the plurality of layers, the first signal VIA being connected to the first conductive trace, the first signal VIA having a first distal end;
a second signal VIA extending through several layers of the plurality of layers, the second signal VIA being connected to the second conductive trace, the second signal VIA having a second distal end; and
a ground VIA extending through several layers of the plurality of layers, the ground VIA being located between the first signal VIA and the second signal VIA, wherein a distance between the first distal end and the bottom layer is a first distance, a distance between the second distal end and the bottom layer is a second distance, and the first distance is less than the second distance.

16. The printed circuit board of claim 15, wherein a portion of the first signal VIA overlaps a portion of the second signal VIA along a Z-axis of the printed circuit board.

17. The printed circuit board of claim 15, wherein the top layer has a top side cage signal structure that has a fanout pattern.

18. The printed circuit board of claim 15, further comprising:
a first microstrip having a first end and a second end; and
a pad, wherein the first signal VIA is connected to the first end of the first microstrip, and the second end of the first microstrip is connected to the pad.

19. The printed circuit board of claim 18, further comprising:
a second microstrip, wherein the first microstrip and second microstrip are arranged in a fanout pattern.

20. The printed circuit board of claim 19, wherein a bottom side signal cage structure on the bottom layer has a VIA in pad type structure.
